(19) United States
(12) Patent Application Publication
(10) Pub. No.: US 2019/0189459 A1
(43) Pub. Date: Jun. 20, 2019

(54) PROCESSING DEVICE FOR THE THIRD GENERATION SEMICONDUCTOR MATERIALS

(71) Applicant: Guangdong University of Technology, Guangzhou (CN)

(72) Inventors: Yun CHEN, Guangzhou (CN); Xin CHEN, Guangzhou (CN); Jian GAO, Guangzhou (CN); Zhengping WANG, Guangzhou (CN); Haidong YANG, Guangzhou (CN)

(21) Appl. No.: 16/221,456

(22) Filed: Dec. 15, 2018

(30) Foreign Application Priority Data
Dec. 15, 2017 (CN) 201711351566.9

(51) Int. Cl. H01L 21/306; H01L 21/308; H01L 21/311; H01L 21/3213; H01L 21/67; G01F 23/64

(52) U.S. Cl. CPC H01L 21/30612; H01L 21/3081; G01F 23/64; H01L 21/3213; H01L 21/67063; H01L 21/311

(57) ABSTRACT

Disclosed is a processing device for the third generation semiconductor materials. The device includes a reaction device, an operating platform and a support device. A reaction chamber is located inside the reaction device and the upper and lower ends of the reaction device are covered with an upper cover and a lower cover, respectively. An etching solution injection port and an etching solution discharge port are provided at the side wall of the reaction chamber. A stirring excitation coil, a plurality of conducting rods, a plurality of heating rods, a plurality of sealing rings and a workpiece are provided inside of the reaction chamber. The stirring excitation coil is mounted just under the upper cover; the conducting rods and the heating rods are respectively mounted in a circumferentially symmetrical manner in an inner wall of the reaction chamber.

### CROSS-REFERENCE TO RELATED APPLICATIONS

This application claims to Chinese Application No. 201711351566.9 with a filing date of Dec. 15, 2017. The content of the aforementioned application, including any intervening amendments thereto, is incorporated herein by reference.

### TECHNICAL FIELD

The disclosure relates to a semiconductor processing, in particular to a processing device for the third generation semiconductor materials.

### BACKGROUND

With the development of science and technology, the demand for electronic devices that can work stably under extreme conditions of high temperature, high frequency, high power, and strong radiation is becoming more and more urgent. Compared to the first and second generation semiconductor materials, the third generation wide band gap (2.3 eV-3.3 eV) semiconductor materials, represented by GaN and SiC, have the nature of higher hardness (Knoop hardness of 3000 Kg/mm²), higher thermal conductivity (EK=4.9 Wcm⁻¹K⁻¹), higher electron saturation velocity, higher radiation resistance (>105 W/cm²), good chemical stability (hardly corroded by any acid) and so on, which have broad prospects in the application of high temperature, high frequency, radiation and high power devices. At present, the research and application of the third generation of semiconductor materials is the frontier and hotspot of the research in the global semiconductor field. However, because of the characteristics of high hardness, high stability, high temperature resistance of the third generation semiconductor, it also has great challenges to process.

Chinese patent CN102290332B, European patent EP2439766A1, U.S. Pat. No. 6,762,134 adopted the metal-assisted chemical etching technique through the catalysis of precious metal nano particles, and used the mixed solution of hydrofluoric acid and oxidant (hydrogen peroxide, ferric nitrate, potassium permanganate and so on) to etch on silicon, GaAs and other semiconductor materials, so that various microporous structures, nanowire structures, micro-nano structures with large depth-to-width ratio are produced. The first generation semiconductor nano-materials, such as silicon (Si), and the second generation semiconductor nano-materials, such as gallium arsenide (GaAs), have a band gap of less than 1.5 eV, which is lower than the redox potential in the etching solution, therefore, various types of microstructure can be etched without the need to apply external physical fields to exert forces. However, the band gap of the third generation semiconductor materials is generally greater than 3 eV, which is much higher than the redox potential of the oxidant in the etching solution, therefore, the conventional etching process cannot directionally process the third generation semiconductor materials.

Chinese patent CN 100449710, CN 101748459 and United States patent US2010140099 proposed the electrochemical device, which directly immerse the semiconductor device in the reaction solution so that redox reaction can be generated only by applying a small voltage. However, when the electrochemical device is used to etch the third generation semiconductor, a sufficiently large voltage drop cannot be directly generated on the semiconductor materials, and a highly controllable processing effect cannot be achieved. In addition, it can only process randomly distributed porous structures, and cannot process ordered arrays of holes, grooves and arrays of nanowires.

In conclusion, there is still a lack of effective etching method and device for processing of the third generation semiconductor materials. An efficient method and device for processing ordered and complex microstructures on the third generation semiconductor materials needs to be further proposed.

### SUMMARY

The object of the present invention is to provide a processing device for the third generation semiconductor materials, which overcomes the problem that it is difficult to efficiently process regular microstructures, such as nanowires, nanoholes, and nanogrooves, on the third generation semiconductor materials to make processing of the third generation semiconductor materials highly efficient and controllable.

To achieve this object, this invention adopted the following technical solutions:

A processing device for the third generation semiconductor materials includes a reaction device, an operating platform and a support device; the reaction device is a cylindrical box with a reaction chamber therein, and the upper and lower ends of the cylindrical box are covered with an upper cover and a lower cover, respectively.

The side wall of the reaction chamber is provided with an etching solution discharge port and an etching solution injection port which locating above the etching solution discharge port, and the etching solution discharge port opening is tangent to a bottom surface of the reaction chamber.

A stirring excitation coil, a plurality of conducting rods, a plurality of heating rods, a plurality of sealing rings and a workpiece are provided inside the reaction chamber; the stirring excitation coil is mounted just under the upper cover; a plurality of conducting rods and a plurality of heating rods are respectively mounted in a circumferentially symmetrical manner mounted in an inner wall of the reaction chamber and are spaced apart from each other; two sealing rings are mounted on the bottom of the reaction chamber, and the two sealing rings are sleeved in the lower cover through a corresponding slot formed on the inner surface of the lower cover; the workpiece is mounted between the two sealing rings.

A first through-hole is provided in the middle of the upper cover and a plurality of coaxial second through-holes are provided in the bottom of the reaction chamber, the sealing rings and the middle of the lower cover respectively; the reaction device is vertically mounted in a middle portion of the supporting device and electrically connected with the operation platform by the first through-hole and the second through-hole on two ends thereof.

Further, the reaction device further includes an inspection adjustment device; the inspection adjustment device includes an ion concentration device, a thermostatic regulator and a liquid level checker. The ion concentration device, the thermostatic regulator and the liquid level checker are symmetrically mounted on the inner wall of the reaction chamber along a center of the shaft and spaced apart from each other.

Further, the supporting device includes a support frame, a punch holder, a die holder and a plurality of bolted connectors; the punch holder is mounted on the top of the support frame and a mounting through-hole is provided in the middle portion of the punch holder, and the reaction device is fixedly mounted in the mounting through-hole; the die holder is mounted under the punch holder by the bolted connectors, the lower cover is connected to the upper surface of the die holder.

Further, eight pressure sensors circumferentially symmetrically distributed are embedded in any one of the sealing rings and electrically connected to the operation platform, and a flatness of two ends faces of the sealing rings is less than 0.01 mm.

Preferably, the reaction chamber is made of organic glass materials with a diameter of 2-12 inches, and the inner wall of the reaction chamber is coated with the polytetrafluoroethylene coating, and an outer wall of the reaction chamber is marked with a scale; surfaces of the components of the reaction device are coated with the polytetrafluoroethylene coating.

Further, a plurality of magnets coated with the polytetrafluoroethylene coating are provided inside the reaction chamber.

Further, the upper cover is provided with a bidirectional exhaust device circumferentially distributed on the outside of the first through-hole.

Further, the operating platform is a visual control platform composed of a DC power generator, a visualized screen, and a PLC integrated control system.

Preferably, the materials of a plurality of conducting rods and a plurality of heating rods are platinum or gold which is hydrofluoric acid; the plurality of conducting rods are four pieces and are electrically connected to a cathode of the DC power generator; the plurality of heating rods are four pieces and are electrically connected to the operating platform.

Preferably, the size of the workpiece is smaller than that of the sealing rings, and the bottom of the workpiece is electrically connected to an anode of the DC power generator; the material of the workpiece is any of the third generation semiconductor of silicon carbide (SiC), gallium nitride (GaN), zinc oxide (ZnO), diamond and aluminum nitride (AlN); and an output voltage of the DC power generator ranges from 0 to 60V.

The benefits of this invention: this invention has effectively processed various micronano structures for the third generation semiconductor, which has overcome the problem that it is difficult to produce regular nanowires, nano holes and nano grooves with high aspect ratio micro structures on the third generation semiconductor materials, which has realized the efficient and controllable processing for various micro structures of the third generation semiconductor materials. It has the characteristics of being simple to operate and control, having consistent and stable processing result, having stable and simple structure, enhancing the controllability of quality for manufacturing, being suitable for microfluidic chip, biochip and microelectronic device, being used for manufacturing and being large potential to be applied.

### BRIEF DESCRIPTION OF THE DRAWINGS

FIG. 1 is a perspective sectional diagram of a processing device for the third generation semiconductor materials according to an embodiment of this invention;

FIG. 2 is a schematic diagram of a processing device for the third generation semiconductor materials according to an embodiment of this invention;

FIG. 3 is a schematic diagram of the upper cover according to an embodiment of this invention;

FIG. 4 is a schematic diagram of the reaction chamber according to an embodiment of this invention;

FIG. 5 is a schematic diagram of the sealing ring according to an embodiment of this invention.

FIG. 6 is a schematic diagram of the lower cover according to an embodiment of this invention;

FIG. 7 is a schematic diagram of the die holder according to an embodiment of this invention;

FIGS. 8-13 are cross-sectional schematic diagram according to an embodiment of this invention.

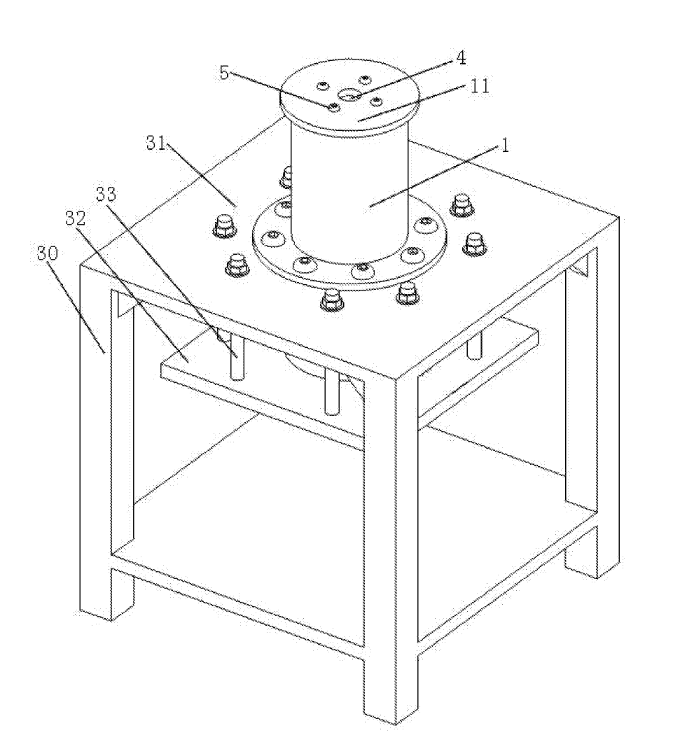

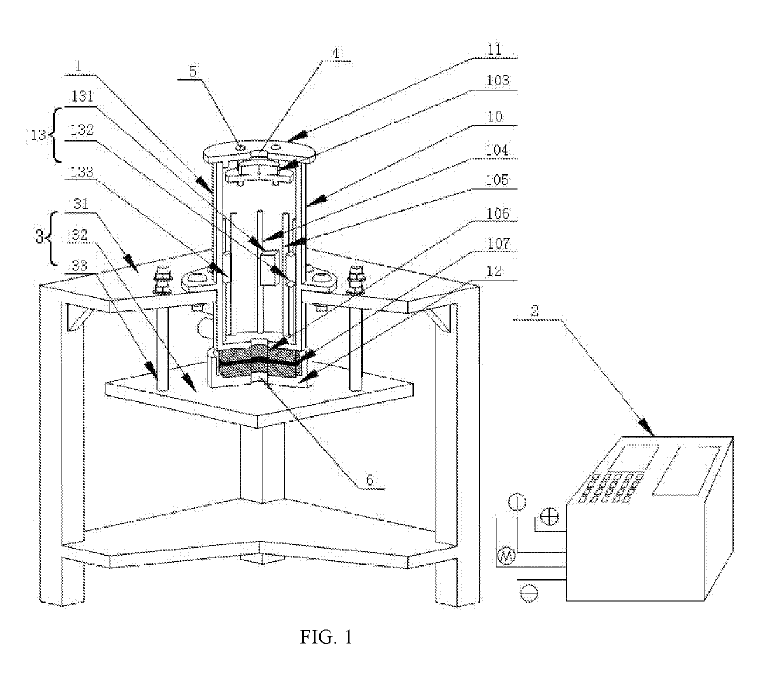

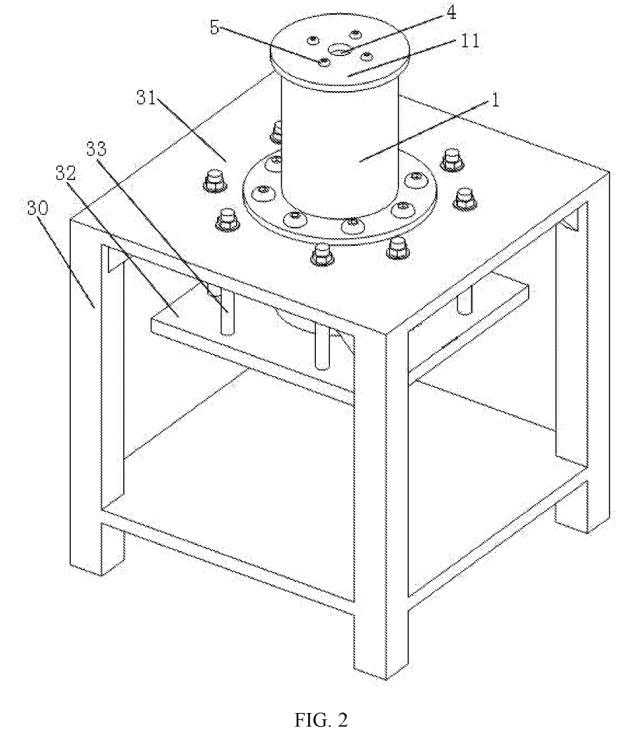

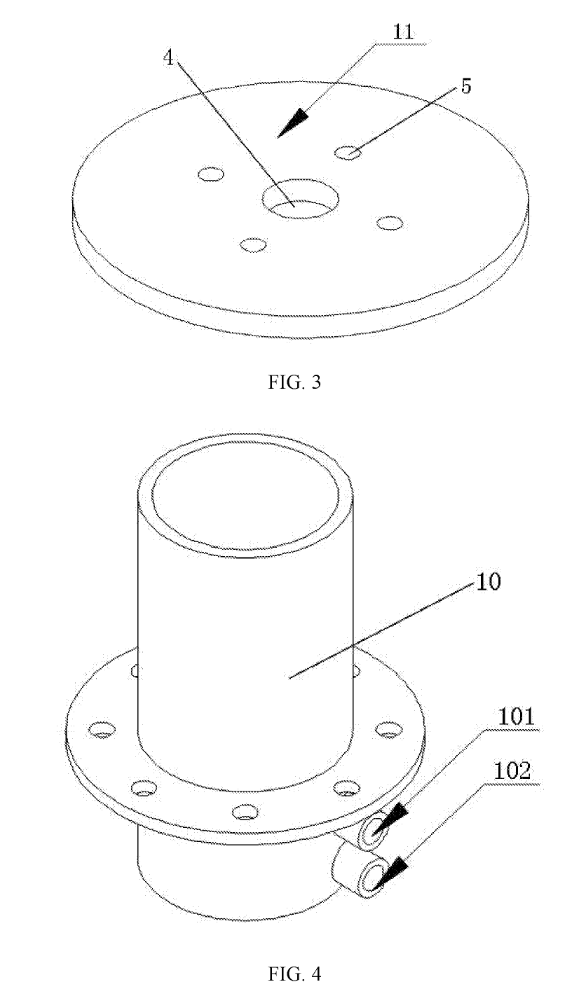

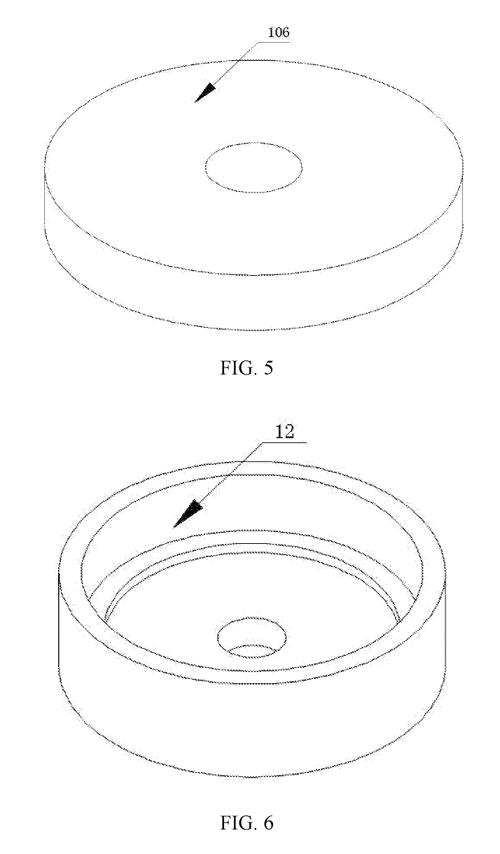

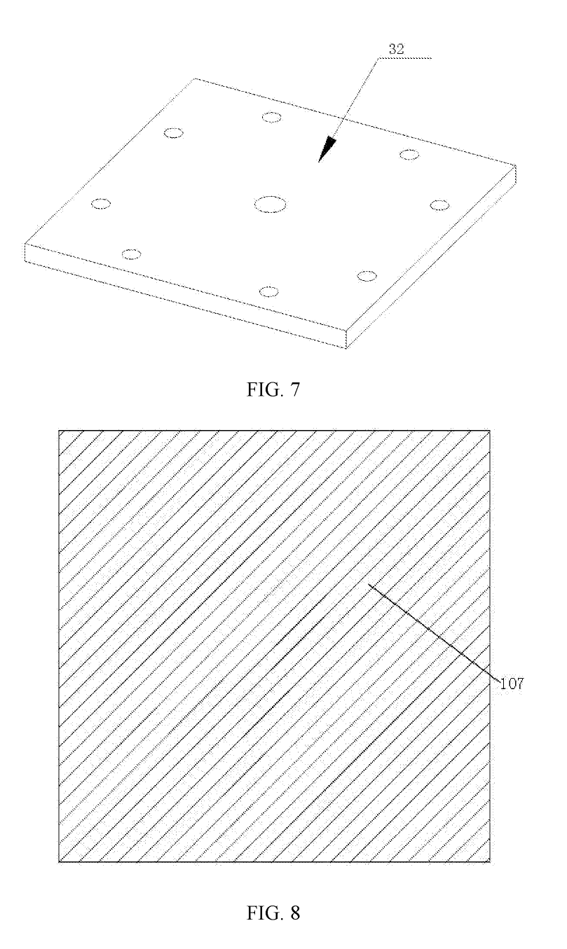

In the drawings: reaction device 1, reaction chamber 10, etching solution injection port 101, etching solution discharge port 102, stirring excitation coil 103, conducting rod 104, heating rod 105, sealing ring 106, workpiece 107, upper cover 11, lower cover 12, inspection adjustment device 13, ion concentration device 131, thermostatic regulator 132, liquid level checker 133, operating platform 2, support device 3, support frame 30, punch holder 31, die holder 32, bolted connector 33, first through-hole 4, bidirectional exhaust device 5, second through-hole 6, photoresist 8, metal layer 9.

### DETAILED DESCRIPTION OF EMBODIMENTS

In the following, the embodiments of the present invention will be described in detail on the basis of the drawings.

A processing device for the third generation semiconductor materials includes a reaction device 1, an operating platform 2 and a support device 3; the reaction device 1 is a cylindrical box with a reaction chamber 10 inside, and the upper and lower ends of the cylindrical box are covered with an upper cover 11 and a lower cover 12, respectively.

The side wall of the reaction chamber 10 is provided with an etching solution discharge port 102 and an etching solution injection port 101 which locating above the etching solution discharge port 102, and the etching solution discharge port 102 opening is tangent to a bottom surface of the reaction chamber 10.

A stirring excitation coil 103, a plurality of conducting rods 104, a plurality of heating rods 105, a plurality of sealing rings 106 and a workpiece 107 are provided inside the reaction chamber 10; the stirring excitation coil 103 is mounted just under the upper cover 11; the conducting rods 104 and the heating rods 105 are respectively mounted in a circumferentially symmetrical manner in an inner wall of the reaction chamber 10 and are spaced apart from each other; two sealing rings are mounted on the bottom of the reaction chamber 10, and the two sealing rings 106 are sleeved in the lower cover 12 through a corresponding slot formed on the inner surface of the lower cover 12; the workpiece 107 is mounted between the two sealing rings 106.

A first through-hole 4 is provided in the middle of the upper cover 11 and a plurality of coaxial second through-holes 6 are provided in the bottom of the reaction chamber 10, the sealing rings 106 and the middle of the lower cover 12 respectively; the reaction device 1 is vertically mounted in a middle portion of the supporting device 3 and is electrically connected with the operation platform 2 by the first through-hole 4 and the second through-hole 6 on two ends thereof.

This invention proposed a processing device for the third generation semiconductor materials, which can efficiently process various micronano structures for the third generation semiconductor materials with the use of precious metal nano particles as catalysis and the synergism effect of the electric field and the etching solution. It has overcome the problem that it is difficult to produce regular nanowires, nano holes and nano grooves with high aspect ratio micro structures on the third generation semiconductor materials, realized the efficient and controllable processing for various micro structures of the third generation semiconductor materials. It has the characteristics of being simple to operate and control, having consistent and stable processing result, having stable and simple structure, enhancing the controllability of quality for manufacturing, being suitable for microfluidic chip, biochip and microelectronic device, being used for manufacturing and being large potential to be applied. Compared with the existing processing device, the processing device of the present invention mainly includes the following features:

1. The processing device structure with special design mounts a plurality of conducting rods 104 on the side wall of the reaction chamber 10 to apply an electric field, and to force the applied direct current easily go through the third generation semiconductor materials and form a certain voltage drop on the third generation semiconductor materials; the temperature of the etching solution in the reaction chamber is controlled to be constant by using the heating rods 105 in the reaction chamber. At the same time, an oxidant may be added to the etching solution to release energy in the redox reaction so that the total energy reaches what required for the oxidation reaction of the third generation semiconductor materials so that the workpiece which contacts with the catalyst of the precious metal nano-particles is efficiently etched, and various nanostructures are efficiently processed. Hence, it is easy to operate.

2. The stirring excitation coil 103 under the upper cover 11 is used to exercise stable magnetic stirring during the processing process to make the concentration of each part keep even so that the processing result of the workpiece consistent and stable.

3. Two sealing rings 106 are provided at the bottom of the reaction chamber 10, and the lower cover 12 is sleeved at the bottom of the sealing rings 106, and the corresponding slot is formed on the inner surface of the lower cover 12, to ensure the through-holes of the bottom of the reaction chamber 10, the sealing rings 106 and the lower cover 12 are coaxial, namely, the second through-hole 6 is effectively obtained, which has achieved the stable and precise mounting of the workpiece 107 and effectively electrical connection by the second through-hole 6. Hence, it has a stable and simple structure.

4. The volume of the etching solution is precisely controlled by the etching solution injection port 101 and the etching solution discharge port 102 to ensure the stability of the etching result. At the same time, it has avoids the manual operation to the etching solution. Hence, it is more safe and reliable.

5. The repeatability of the etching reaction is improved and the consistency of each reaction parameter is ensured, and the controllability of manufacturing quality is enhanced by the program control of the operating platform 2.

Further, the reaction device 1 is further provided with an inspection adjustment device 13 which includes an ion concentration device 131, a thermostatic regulator 132 and a liquid level checker 133. The ion concentration device 131, the thermostatic regulator 132 and the liquid level checker 133 are symmetrically mounted on the inner wall of the reaction chamber 10 along a center of the shaft and spaced apart from each other. The inspection adjustment device 13 can effectively monitor the particle concentration, temperature and the height of the liquid surface of the etching solution in the reaction chamber 10, which can control the processing of the workpiece and improve the processing effect.

Further, the supporting device 3 includes a support frame 30, a punch holder 31, a die holder 32 and a plurality of bolted connectors 33; the punch holder 31 is mounted on the top of the support frame 30 and a mounting through-hole is provided in the middle portion of the punch holder 31, and the reaction device 1 is fixedly mounted in the mounting through-hole; the die holder 32 is mounted under the punch holder 31 by the bolted connectors 33, the lower cover 12 is connected to the upper surface of the die holder 32.

The reaction device 1 is mounted and fixed by using the punch holder 31 and the die holder 32 with the connection of the bolted connectors 33, which can not only improve the stability of the reaction device 1, but also it can flexibly adjust the reaction device 1 by using the bolted connectors to mount the die holder 32 under the punch holder 31 to make the mounting of the workpiece 107 more precise.

Further, eight pressure circumferentially symmetrically distributed are embedded in one of the sealing rings and electrically connected to the operating platform 2, and a flatness of two end faces of the sealing rings 106 is less than 0.01 mm. To provide the pressure sensors in the sealing ring 106 is to precisely control the pre-tightening force of the workpiece 107 to be even and to keep the workpiece 107 fully sealed when mounting the workpiece 107. The even force of the workpiece 107 can be ensured by monitoring the values of pressure sensors to be same.

Preferably, the reaction chamber 10 is made of organic glass materials with a diameter of 2-12 inches, and the inner wall thereof is coated with the polytetrafluoroethylene coating, and an outer wall of the reaction chamber 10 is marked with a scale; surfaces of the components of the reaction device 1 are coated with the polytetrafluoroethylene coating. The polytetrafluoroethylene coating is adopted to prevent corrosion, and it is high-temperature resistant.

Further, a plurality of magnets coated with the polytetrafluoroethylene coating are provided inside the reaction chamber 10. The magnets are immersed in the etching solution in the reaction chamber 10, and the movement of the magnets can be effectively controlled by using the magnetic field to stir the stirring excitation coil 103 to obtain power during the processing to make the concentration of each part of the etching solution more even.

Further, the upper cover is provided with a bidirectional exhaust device 5 circumferentially distributed on the outside of the first through-hole 5. The bidirectional exhaust device can extract volatile gases generated in the reaction chamber during the reaction process.

Further, the operating platform 2 is a visual control platform composed of a DC power generator, a visualized screen, and a PLC integrated control system.

Preferably, the materials of a plurality of conducting rods 104 and a plurality of heating rods 105 are platinum or gold which is hydrofluoric acid; a plurality of conducting rods 104 are four pieces and are electrically connected to a cathode of the DC power generator; a plurality of heating rods 105 are four pieces and are electrically connected to the operating platform.

Preferably, the size of the workpiece 107 is smaller than that of the sealing rings 106, and the bottom of the workpiece 107 is electrically connected to an anode of the DC power generator; the material of the workpiece 107 is any of the third generation semiconductor of silicon carbide (SiC), gallium nitride (GaN), zinc oxide (ZnO), diamond and aluminum nitride (AlN); an output voltage of the DC power generator ranges from 0 to 60V.

A cathode of the DC power generator is connected with the conducting rods 104 in the reaction chamber by the first through-hole 4 and an anode of the DC power generator is attached to the lower surface of the workpiece 107 by the second through-holes 6, and an output voltage range of the DC power generator is controlled, so that a certain voltage drop is effectively formed on the third generation semiconductor to let the workpiece 107 etch effectively.

The detailed processing is as follows:

Step 1: processing before etching: first, immersing a silicon carbide workpiece 107 with a size of 10 cm*10 cm in a 120° C. mixed hot solution of concentrated sulfuric acid (mass concentration: 96%) and hydrogen peroxide (mass concentration: 30%) at a volume ratio of 1:1 for 10 minutes to completely remove the oxide on the surface of the workpiece 107; then, taking off the workpiece 107 from the solution and rinsing it with a large amount of deionized water; then drying it in the nitrogen gas flow, taking it out after dried; as shown in FIG. 8;

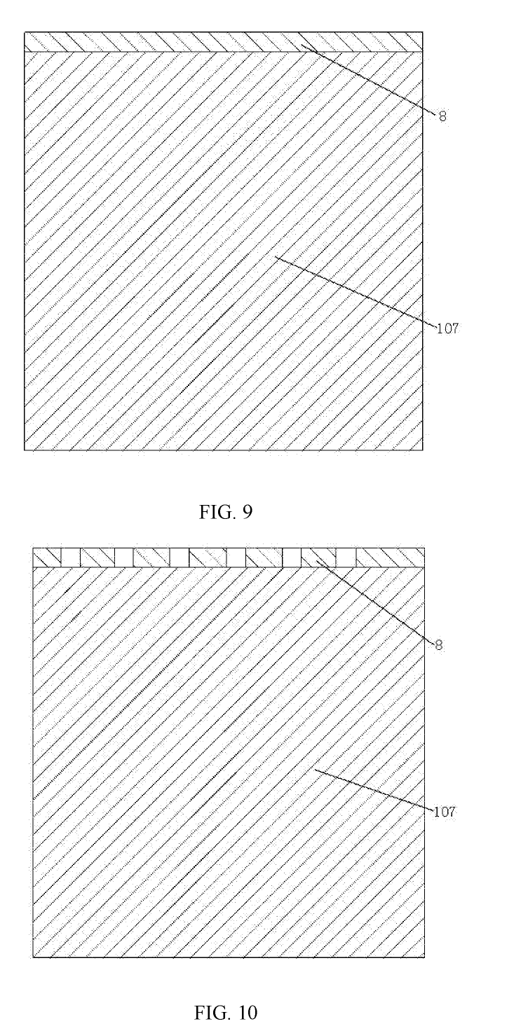

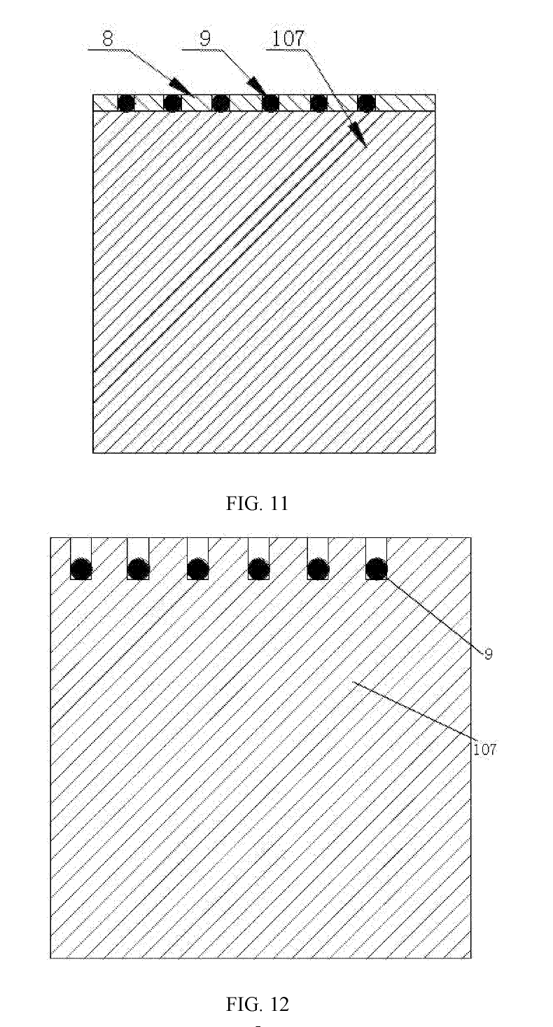

step 2: coating a photoresist 8 with the thickness of about 400 nm by spin-coating on the workpiece 107 obtained from step 1, as shown in FIG. 9; drying and placing on the mask aligner for exposure, and removing the unexposed photoresist by the development, as shown in FIG. 10; then, reducing the thickness of exposed photoresist to 200 nm by reactive ion etching (RIE) for 2-3 minutes and removing the residual unexposed photoresist; next, 3 nm Ti and 30 nm Au are sequentially evaporated on the workpiece 107 and the evaporation time is about 30 minutes. Since the exposed photoresist acts as a mask, a metal layer 9 having a needed microstructure shape can be produced on the workpiece 107; as shown in FIG. 11;

step 3: Using the above processing device for the third generation semiconductor to process. Starting and initializing the device, debugging the reaction device 1, the operating platform 2 and the support device 3 to make it in a ready condition of the initialization; the stirring excitation coil 103, the magnets, the conducting rods 104, the heating rods, the ion concentration device 131, the thermostatic regulator 132, the liquid level checker 133 and the pressure sensors are in a ready condition; checking the air-tightness and patency of the connecting tubes; placing the workpiece 107 obtained from step 2 in the sealing rings 106, attaching an anode of the DC power to the lower surface of the workpiece 107, observing the pressure sensors from the operating platform 2, tightening the bolted connectors to make the pre-tightening force of the workpiece 107 even and the workpiece fully sealed, and to make the values of the pressure sensors to be same;

Step 4: preparing the etching solution: slowly adding hydrofluoric acid, oxidant and water with the ratio of 1:1:1 from the etching solution injection port 101. Connecting the cathode of DC power with the conducting rods 104 in the etching chamber and covering the upper cover 11. At the same time, starting the stirring excitation coil 103 to control the movement of magnets, stirring during the etching processing to make the concentration of the etching solution in the etching chamber even;

Step 5: according to the shape of the nanopore to be formed, adjusting the DC voltage to be 10 V by setting the parameters of the operating platform 2, and controlling temperature of the etching solution to be constant with 50° C. by using the heating rods 105 of the chamber. According to the depth of the nanopore to be formed, the rate of corrosion is estimated to be 0.5-5 μm/min, and the etching time is obtained according to the depth of the nanopore to be formed divided by the rate at which the material is etched. The corrosion rate is controlled by the chemical reaction, and the processing time of each etching process is calculated based on it, as shown in FIG. 12;

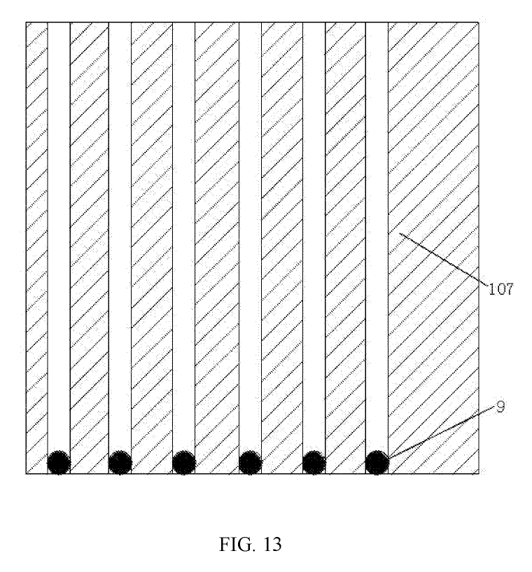

Step 6: according to the set reaction time, the system prompts the completion of the reaction when the etching reaction time is up. Starting the bidirectional exhaust device 5 to extract gases such as hydrofluoric acid volatilized during the reaction. Draining the etching solution by the etching solution discharge port 102, and loosening a plurality of bolted connectors 33, taking out the workpiece which is obtained after the etching processing is finished, rinsing with deionized water and drying with nitrogen, and the required nanopore arrays are obtained on the workpiece 107, as shown in FIG. 13;

Step 7: cleaning the processing device for etching the microstructure, completing the etching process; saving the data of the system to prepare multiple invocations of the etching process.

The technical principles of the present invention have been described above according to the detailed embodiments. These descriptions are only intended to explain the principles of the invention and can not to be explained as limiting the scope of the invention. Based on the explanation herein, other embodiments of this invention which can be associated by those skilled in prior art without creative steps are within the scope of this invention.

What is claimed is:

1. A processing device for the third generation semiconductor materials, comprising:
a reaction device;
an operating platform; and
a support device;
wherein the reaction device is a cylindrical box with a reaction chamber therein, and upper and lower ends of the cylindrical box are covered with an upper cover and a lower cover, respectively;
the side wall of the reaction chamber is provided with an etching solution discharge port and an etching solution injection port locating above the etching solution discharge port; and the etching solution discharge port opening is tangent to a bottom surface of the reaction chamber;
a stirring excitation coil, a plurality of conducting rods, a plurality of heating rods, a plurality of sealing rings and a workpiece are provided inside the reaction chamber; the stirring excitation coil is mounted just under the upper cover; the conducting rods and the heating rods are respectively mounted in a circumferentially symmetrical manner in an inner wall of the reaction chamber and are spaced apart from each other; wherein two sealing rings are mounted on the bottom of the reaction chamber, and the two sealing rings are sleeved in the lower cover through a corresponding slot formed on the inner surface of the lower cover; the workpiece is mounted between the two sealing rings;
a first through-hole is provided in the middle of the upper cover and a plurality of coaxial second through-holes are provided in the bottom of the reaction chamber, the sealing rings and the middle of the lower cover respectively; the reaction device is vertically mounted in a middle portion of the supporting device and electrically connected with the operation platform by the first through-hole and the second through-hole on two ends thereof.

2. The processing device of claim 1, wherein the reaction device further comprises an inspection adjustment device; the inspection adjustment device includes an ion concentration device, a thermostatic regulator and a liquid level checker; the ion concentration device, the thermostatic regulator and the liquid level checker are symmetrically mounted on the inner wall of the reaction chamber along a center of the shaft and spaced apart from each other.

3. The processing device of claim 1, wherein the supporting device includes a support frame, a punch holder, a die holder and a plurality of bolted connectors; the punch holder is mounted on the top of the support frame and a mounting through-hole is provided in the middle portion of the punch holder, and the reaction device is fixedly mounted in the mounting through-hole; the die holder is mounted under the punch holder by the bolted connectors, the lower cover is connected to the upper surface of the die holder.

4. The processing device of claim 1, wherein eight pressure sensors circumferentially symmetrically distributed are embedded in any one of the sealing rings and electrically connected to the operation platform; and a flatness of two end faces of the sealing rings is less than 0.01 mm.

5. The processing device of claim 1, wherein the reaction chamber is made of organic glass materials with a diameter of 2-12 inches, and the inner wall thereof is coated with the polytetrafluoroethylene coating; an outer wall of the reaction chamber is marked with a scale; surfaces of the components of the reaction device are coated with the polytetrafluoroethylene coating.

6. The processing device of claim 1, wherein a plurality of magnets coated with the polytetrafluoroethylene coating are provided inside the reaction chamber.

7. The processing device of claim 1, wherein the upper cover is provided with a bidirectional exhaust device circumferentially distributed on the outside of the first through-hole.

8. The processing device of claim 1, wherein the operating platform is a visual control platform composed of a DC power generator, a visualized screen, and a PLC integrated control system.

9. The processing device of claim 8, wherein the plurality of conducting rods and the plurality of heating rods are made of platinum or gold hydrofluoric acid resistant conductive material; the plurality of conducting rods are four pieces and are electrically connected to a cathode of the DC power generator; the plurality of heating rods are four pieces and are electrically connected to the operating platform.

10. The processing device of claim 8, wherein the size of the workpiece is smaller than that of the sealing rings, and the bottom of the workpiece is electrically connected to an anode of the DC power generator; the material of the workpiece is any of the third generation semiconductor of silicon carbide (SiC), gallium nitride (GaN), zinc oxide (ZnO), diamond and aluminum nitride (AlN); and an output voltage of the DC power generator ranges from 0 to 60V.
